(19) United States
(12) Patent Application Publication
(10) Pub. No.: US 2009/0206870 A1
(43) Pub. Date: Aug. 20, 2009

(54) METHOD FOR ANALYZING IC DEVICES AND WAFERS

(76) Inventors: MENG YU HUANG, Xianxi Shiang (TW); Tsai Li Lee, Xihu Town (TW); Chin Tsair Chen, Dapi Shiang (TW); Ming Hsieh Tsai, Hsinchu (TW)

Correspondence Address: HOLLAND & KNIGHT LLP, 10 ST. JAMES AVENUE, BOSTON, MA, 02116-3889, US

(21) Appl. No.: 12/188,633

(22) Filed: Aug. 8, 2008

(30) Foreign Application Priority Data
Feb. 15, 2008 (TW) 097105481

(51) Int. Cl. G01R 31/26

(52) U.S. Cl. 324/765; 702/58

(57) ABSTRACT

A method for analyzing Integrated circuit (IC) devices is provided. The method comprises the following steps: dividing an IC device into n working units, wherein each working unit causes a corresponding current dissipation; selecting n operation parameters, wherein each of the operation parameters variably corresponds to the current dissipation of each working unit; selecting m sets of the operation parameters and separately operating the IC device under the m sets of the operation parameters, wherein m is not smaller than n, and obtaining the total current dissipations of the IC device; computering m sets of current dissipation data of the working units corresponding to the m sets of operation parameters by using the total current dissipations; computering a basic current dissipation of the IC device by using the total current dissipations of the IC device and the obtained corresponding current dissipation data set of the working units; and determining the defective working units by comparing the obtained data with the standard data, respectively.

### RELATED APPLICATION

This application claims priority to Taiwan Patent Application No. 097105481 filed on Feb. 15, 2008.

### BACKGROUND OF THE INVENTION

1. Field of the Invention

The present invention provides a method for analyzing an integrated circuit (IC) device and a wafer. In particular, the present invention provides a method for analyzing an IC device and a wafer by using current dissipations.

2. Descriptions of the Related Art

Currently, most methods for analyzing IC devices compare the voltage value or time value thereof against a standard value to determine whether or not the IC device is defective. For example, the power supply voltage (VDD) or bias of the analyzed IC device is measured and then compared against that of a standard IC device. If there is a substantial difference therebetween, then the analyzed IC device is deemed defective. Alternatively, the write recovery time (tWR) or row precharge time (tRP) of the analyzed IC device is measured and then compared against that of a standard IC device. If there is a substantial difference therebetween, then the analyzed IC device is deemed defective.

However, the methods described above only superficially determine whether an IC device is defective, and fail to directly detect the underlying cause that renders the IC device defective. For example, if two semiconductor devices are determined to be defective because of a damaged core circuit and a damaged peripheral circuit respectively, the above methods can only tell that the two devices are defective, but are unable to give a specific reason for why the individual device is defective. Therefore, to more accurately find out the reason that accounts for the defect, the inspection staff has to conduct further tests and analysis in other ways, which inevitably incurs increased costs in terms of both time and labor. Furthermore, when a semiconductor device is damaged to such an extent that it fails to generate a signal or causes an abnormal current dissipation, or even when a standard value is unavailable for comparison, results obtained from these methods will become more difficult to analyze.

In addition, the above methods, when used to make an analysis on a wafer, can only tell which semiconductor device on the wafer is a failure block, but cannot give the actual reason that has resulted in such a failure. Consequently, it is difficult to improve the wafer manufacturing process accordingly in a minimum time period.

It can be seen from the above descriptions that the analyzing methods of the prior art can only determine whether or not a semiconductor device is defective, but not give the underlying reason that causes such a defect. In view of this, it is highly desirable in the art to provide a method that is capable of determining the underlying reasons that lead to the defects of an IC device.

### SUMMARY OF THE INVENTION

This invention provides a method for analyzing an IC device or a wafer by using current dissipations. Particularly, by dividing an IC device into different working units and selecting operation parameters, the corresponding current dissipations of the working units can be obtained by selecting the operation parameters. The current dissipations thus obtained may not only be used to determine whether or not the IC device is defective, but also render it possible to further determine whether an individual working unit thereof is a failure block.

This invention provides a method for analyzing an IC device with the following steps: dividing the IC device into n working units (W₁, W₂, . . . , Wₙ), wherein each working unit causes a corresponding current dissipation (I_{wk}, k=1˜n), and the current dissipations (I_{wk}) of the working units are set to be independent from each other; selecting n operation parameters (X₁, X₂, . . . , Xₙ) for operating the IC device, wherein the operation parameters (Xₖ) are in an one-to-one correspondence with the current dissipations (I_{wk}) of the working units, and the change of one operation parameter substantially affects the current dissipation data of one working unit; selecting m sets of operation parameters (X_{1,j}, X_{2,j}, . . . , X_{n,j}, j=1˜m) and separately operating the IC device under the conditions of the m set operation parameters to obtain corresponding total current dissipations (I_{t,j}) of the IC device, wherein m is not smaller than n; computering m sets of current dissipation data (I_{w1,j}, I_{w2,j}, . . . , I_{wn,j}) of the working units corresponding to the m sets of operation parameters (X_{1,j}, X_{2,j}, . . . , X_{n,j}, j=1˜m) by using the total current dissipations (I_{t,j}); computering a basic current dissipation (I_{DC}) of the IC device by using one of the total current dissipations (I_{t,j}) of the IC device and the obtained corresponding current dissipation data set (I_{w1,j}, I_{w2,j}, . . . , I_{wn,j}) of the working units; and comparing at least one set of the obtained current dissipation data (I_{DC}, I_{w1,j}, I_{w2,j}, . . . , I_{wn,j}) with a set of standard current dissipation data (I^{s}_{DC}, I^{s}_{w1,j}, I^{s}_{w2,j}, . . . , I^{s}_{wn,j}) individually, wherein the standard current dissipation data (I^{s}_{DC}, I^{s}_{w1,j}, I^{s}_{w2,j}, . . . , I^{s}_{wn,j}) is a combination of a standard basic current dissipation of a standard IC device (I^{s}_{DC}) and a corresponding standard current dissipation data set of the standard working units (I^{s}_{w1,j}, I^{s}_{w2,j}, . . . , I^{s}_{wn,j}). If a substantial difference is found through the one or more corresponding comparisons, the IC device is determined to be defective. In this way, it is also possible to tell which working unit is defective.

This invention provides a method for analyzing a wafer, wherein the wafer has a plurality of IC devices. The method comprises the following steps: analyzing each of the IC devices by using the method described above to determine whether the IC device is defective or not; and calculating the ratio of the number of defective IC devices to that of the fine IC devices to determine if the wafer is a defective wafer.

The detailed technology and preferred embodiments implemented for the subject invention are described in the following paragraphs accompanying the appended drawings for people skilled in this field to well appreciate the purposes, features, and advantages of the claimed invention.

### BRIEF DESCRIPTION OF THE DRAWINGS

FIG. 1 is a schematic flow diagram of a method of analyzing an IC device in accordance with this invention.

### DESCRIPTION OF THE PREFERRED EMBODIMENT

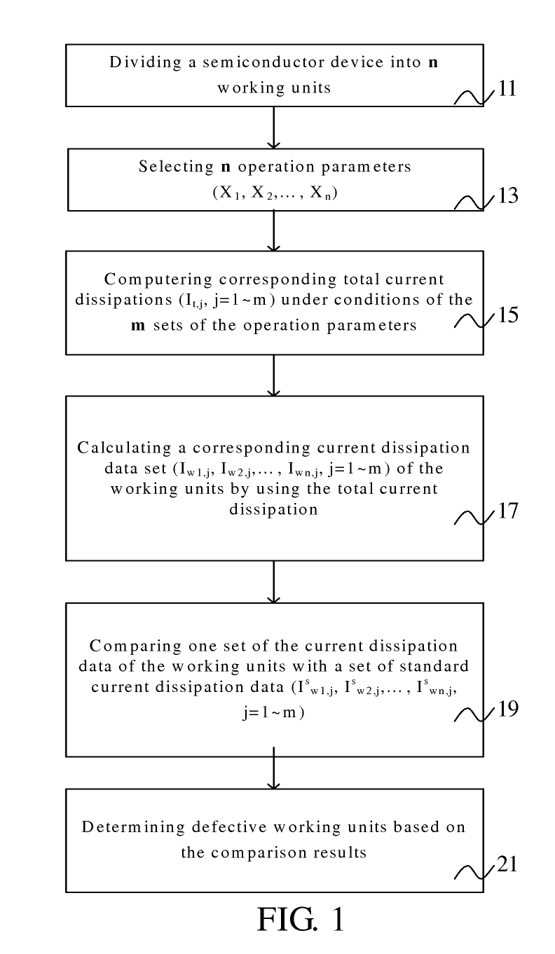

FIG. 1 is a schematic flow diagram of a method of analyzing an IC device in accordance with this invention. Generally, an IC device can typically be divided into several primary circuits, operation of which depends on a plurality of operation parameters. According to this invention, initially, an IC device is divided into n working units (W₁, W₂, . . . , Wₙ). Each of the working units causes a corresponding current dissipation (I_{wk}, k=1˜n), and the current dissipations (I_{wk}) of the working units are set to be independent from each other. A total current dissipation (Iₜ) is in a first mathematic relationship with the current dissipations (I_{wk}) of the working units.

Then, the n operation parameters (X₁, X₂, . . . , Xₙ) are selected as variables for operating the IC device, while other operation parameters that are not selected remain constant in value. During the operation of the IC device, the current dissipations (I_{wk}) of the working units are in an one-to-one correspondence with the n selected operation parameters (Xₖ, k=1˜n). Also, the current dissipations (I_{wk}) and the n selected operation parameters (Xₖ, k=1˜n) are substantially in a second mathematic relationship (I_{wk}=f(Xₖ), k=1˜n). That is, during a particular operation, the change of one operation parameter corresponds to the change in the current dissipation of only one working unit.

In other words, according to the method of this invention, the change of one operation parameter substantially affects the current dissipation data of only one working unit. For example, a first operation parameter (X₁) is associated with current dissipation (I₁) of a first working unit (W₁) substantially in a linear relationship, and is unassociated with the other operation parameters (Xₖ, k=2˜n). Hence, the change of the first operation parameter (X₁) substantially affects the current dissipation (I₁) of only the first working unit (W₁).

Afterwards, m sets of the operation parameters (X_{1,j}, X_{2,j}, . . . , X_{n,j}, j=1˜m) are selected, wherein m is not smaller than n. Then, the IC device is operated under the conditions of each set of operation parameters respectively to obtain the corresponding total current dissipations (I_{t,j}, j=1˜m) of the IC device under each set of operation parameters. Next, m sets of current dissipation data (I_{w1,j}, I_{w2,j}, . . . , I_{wn,j}, j=1˜m) of the working units corresponding to the m sets of operation parameters are calculated from the total current dissipations (I_{t,j}), using the first mathematic relationship between the total current dissipations (Iₜ) and the current dissipations (I_{wk}) of the working units during the operation and the second mathematic relationship between each operation parameter (Xₖ) and the current dissipation (I_{wk}) of the corresponding working unit.

For example, during the operation of an IC device, the following first mathematic relationships exist between the total current dissipations (I_{t,j}) and the current dissipations (I_{wk,j}) of the working units.

(1) I_{t,j}=I_{DC}+I_{w1,j}+I_{w2,j}+ . . . +I_{wn,j}, wherein I_{DC} represents a basic current dissipation of the IC device and j=1˜m; and

(2) When only one of the n operation parameters (Xₖ) is changed in value with other operation parameters remaining unchanged, the difference between the two total current dissipations (ΔIₜ) measured under two sets of the operation parameters is substantially equal to the difference between the two current dissipations (ΔI_{wk}) of the working units corresponding to the changed operation parameters.

Furthermore, if the second mathematic relationship between each of the operation parameters (Xₖ) and the current dissipation (I_{wk}) of the corresponding working unit is linear (i.e., I_{wk}=αₖXₖ+βₖ, ≠0 and k=1˜n), m total current dissipations (I_{t,j}, j=1˜m) may be measured optionally under m sets of the operation parameters (m≧n) by changing only one operation parameter each time. Based on this, αₖ and βₖ are derived according to the relationship (2), thereby to obtain the sets of the current dissipation data (I_{w1,j}, I_{w2,j}, . . . , I_{wn,j}, j=1˜m) of the working units under the m sets of the operation parameters according to the relationship I_{wk}=αₖXₖ+βₖ. Then, the basic current dissipation (I_{DC}) is calculated according to the above relationship (1) by using one current dissipation data set (I_{w1,j}, I_{w2,j}, . . . , I_{wn,j}) of the working units and the corresponding total current dissipation (I_{t,j}).

Then, under a particular set of the operation parameters, one set of the obtained current dissipation data (I_{DC}, I_{w1,j}, I_{w2,j}, . . . , I_{wn,j}) is compared with a set of standard current dissipation data (I^{s}_{DC}, I^{s}_{w1,j}, I^{s}_{w2,j}, . . . , I^{s}_{wn,j}, j=1˜m) individually, wherein the standard current dissipation data (I^{s}_{DC}, I^{s}_{w1,j}, I^{s}_{w2,j}, . . . , I^{s}_{wn,j}, j=1˜m) is a combination of a standard basic current dissipation (I^{s}_{DC}) of a standard IC device with n standard working units and corresponding standard current dissipation data set (I^{s}_{w1,j}, I^{s}_{w2,j}, . . . , I^{s}_{wn,j}, j=1˜m) of the standard working units. Here, this process can be repeated to measure one standard total current dissipation (I^{s}_{t,j}, j=1˜m) of the standard IC device under each of the m sets of the operation parameters (X_{1,j}, X_{2,j}, . . . , X_{n,j}, j=1˜m), and then calculate m sets of corresponding standard current dissipation data (I^{s}_{w1,j}, I^{s}_{w2,j}, . . . , I^{s}_{wn,j}, j=1˜m) of the standard working units by using these standard total current dissipations (I^{s}_{t,j}). Then, the standard basic current dissipation (I^{s}_{DC}) can be obtained.

If there is a substantial difference between the aforesaid one or more corresponding comparisons, the IC device is determined to be defective. In this way, it is also possible to tell which working unit is defective.

Hereinafter, the principal of this method will be explained with a dynamic random access memory (DRAM) device as an example. Here, the DRAM device is known to have a plurality of circuits, the operation parameters of which include a row cycle time (tRC), a clock cycle time (tCK) and other operation parameters.

Initially, the DRAM device is divided into two working units, namely, a core working unit with a current dissipation (I_{AC1}) that changes as a function of the operation parameter tRC and a peripheral working unit with a current dissipation (I_{AC2}) that changes as a function of the operation parameter tCK. The two working units comprise different circuit portions of the DRAM device, respectively. Additionally, the two operation parameters, i.e., tRC and tCK, are selected, while other parameters are kept constant.

During the operation of the DRAM device, a total current dissipation (It) thereof and the current dissipations (I_{AC1} and I_{AC2}) of the working units have a first mathematic relationship represented as follows:

(1) Iₜ=I_{DC}+I_{AC1}+I_{AC2} (a)

where I_{DC} represents the basic current dissipation that does not change as a function of tRC and tCK, and has a constant value; and

(2) During the operation of the DRAM device, when either of the operation parameters tRC and tCK is fixed while the other is changed, the difference between the two total current dissipations (ΔIₜ) measured under two sets of the operation parameters is substantially equal to the difference between the two current dissipations (ΔI_{ACn}, n=1 or 2) of the particular working unit corresponding to the changed operation parameter.

It is obvious from the relationship (2) that when tCK is fixed while tRC is changed, the difference (ΔIₜ=Iₜ₁−Iₜ₂) between two total current dissipations (Iₜ₁ and Iₜ₂) measured under the two sets of the operation parameters (tRC₁, tCK₁) and (tRC₂, tCK₂) (where tCK₁=tCK₂) is substantially equal to the difference between the two current dissipations (ΔI_{AC1}=I_{AC1,1}−I_{AC1,2}) of the core working unit, i.e., ΔIₜ=ΔI_{AC1}. On the contrary, when tRC is fixed while tCK is changed, the difference (ΔIₜ′=Iₜ₁′−Iₜ₂′) between the two total current dissipations (Iₜ₁′ and Iₜ₂′) measured under the two sets of the operation parameters is substantially equal to the difference between the two current dissipations (ΔI_{AC2}=I_{AC2,1}−I_{AC2,2}) of the peripheral working unit, i.e., ΔIₜ′=ΔI_{AC2}.

Furthermore, as well-known to those with ordinary skill in the art, I_{AC1} is proportional to tRC and I_{AC2} is proportional to tCK, i.e., I_{AC1}=α₁·tRC and I_{AC2}=α₂·tCK. By selecting the different sets of (tRCⱼ, tCKⱼ), α₁ and α₂ can be derived, thus obtaining the current dissipations (I_{AC1,j}) of the core working unit and current dissipations (I_{AC2,j}) of the peripheral unit under the different sets of (tRCⱼ, tCKⱼ). Based on this, I_{DC} can be derived.

More specifically, in this embodiment, three sets of (tRC, tCK) are selected, which are (tRC₁, tCK₁), (tRC₂, tCK₂) and (tRC₃, tCK₃) respectively, where tRC₁=tRC₂ and tCK₁=tCK₃. Total current dissipations I_{t,1}, I_{t,2} and I_{t,3} are measured under the three sets of the operation parameters, respectively:

I_{t,1}=I_{DC}+I_{AC1,1}+I_{AC2,1}, i.e., I_{t,1}=I_{DC}+α₁ tRC₁+α₂ tCK₁ (a)

I_{t,2}=I_{DC}+I_{AC1,2}+I_{AC2,2}, i.e., I_{t,2}=I_{DC}+α₂ tRC₂+α₂ tCK₂ (b)

I_{t,3}=I_{DC}+I_{AC1,3}+I_{AC2,3}, i.e., I_{t,3}=I_{DC}+α₃ tRC₃+α₂ tCK₃ (c)

Then, by subtracting (b) from (a) and subtracting (c) from (a), we obtain:

I_{t,1}−I_{t,2}=α₂(tCK₁−tCK₂) (d)

I_{t,1}−I_{t,3}=α₁(tRC₁−tRC₃) (e)

Thus, α₂ and α₁ can be derived from the equations (d) and (e), respectively. Then, (I_{AC1,1}, I_{AC1,1}), (I_{AC1,2}, I_{AC2,2}) and (I_{AC1,3}, I_{AC2,3}) can be obtained by substituting the corresponding sets (tRC₁, tCK₁), (tRC₂, tCK₂) and (tRC₃, tCK₃) respectively into the equations I_{AC1}=α₁·tRC and I_{AC2}=α₂·tCK. By substituting any set of (I_{AC1,j}, I_{AC2,j}) and corresponding I_{t,j} (j=1˜3) into the equations (a), (b) or (c), a value of I_{DC} can be obtained.

Finally, one standard current dissipation data (I^{s}_{DC}, I^{s}_{AC1,1}, I^{s}_{AC2,1}) of a standard DRAM device under the first set of the operation parameters are taken and compared with the calculated current dissipation data (I_{DC}, I_{AC1,1}, I_{AC2,1}) of the aforementioned analyzed DRAM device. If there is a substantial difference between one or more corresponding comparisons, the IC device is determined to be defective. By such comparisons, it is also possible to tell which working unit is defective. For instance, if there is a substantial between I_{AC2,1} and I^{s}_{AC2,1}, then the peripheral working unit of the DRAM device to be analyzed is determined to be defective. Furthermore, the standard current dissipation data (I^{s}_{DC}, I^{s}_{AC1,1}, I^{s}_{AC2,1}) of the standard DRAM device may also be obtained by the calculation according to the aforesaid steps of the method of this invention.

The analyzing method of this invention may also be applied during the inspection of a semiconductor wafer. Briefly speaking, each semiconductor device on the wafer is analyzed by using the aforementioned method. If the number of defective semiconductor devices on the wafer exceeds an allowed number, the wafer is determined to be defective. Moreover, based on the working unit known to be defective, the underlying cause that accounts for such a defect in the wafer manufacturing process can be further analyzed.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A method for analyzing an integrated circuit (IC) device, comprising:
dividing the IC device into n working units (W₁, W₂, . . . , Wₙ), wherein each working unit causes a corresponding current dissipation (I_{wk}, k=1˜n), and the current dissipations (I_{wk}) of the working units are set to be independent from each other;
selecting n operation parameters (X₁, X₂, . . . , Xₙ) for operating the IC device, wherein the operation parameters (Xₖ) are in an one-to-one correspondence with the current dissipations (I_{wk}) of the working units, and the change of one operation parameter substantially affects the current dissipation data of one working unit;
selecting m sets of the operation parameters (X_{1,j}, X_{2,j}, . . . , X_{n,j}, j=1˜m) and separately operating the IC device under the conditions of the m sets of the operation parameters to obtain corresponding total current dissipations (I_{t,j}) of the IC device, wherein m is not smaller than n;
computering m sets of current dissipation data (I_{w1,j}, I_{w2,j}, . . . , I_{wn,j}) of the working units corresponding to the m sets of operation parameters (X_{1,j}, X_{2,j}, . . . , X_{n,j}, j=1˜m) by using the total current dissipations (I_{t,j});
computering a basic current dissipation (I_{DC}) of the IC device by using one of the total current dissipations (I_{t,j}) of the IC device and the obtained corresponding current dissipation data set (I_{w1,j}, I_{w2,j}, . . . , I_{wn,j}) of the working units; and
comparing at least one set of the obtained current dissipation data (I_{DC}, I_{w1,j}, I_{w2,j}, . . . , I_{wn,j}) with a set of standard current dissipation data (I^{s}_{DC}, I^{s}_{w1,j}, I^{s}_{w2,j}, . . . , I^{s}_{wn,j}) individually, wherein I^{s}_{DC} is a standard basic current dissipation of a standard IC device having n standard working units and (I^{s}_{w1,j}, I^{s}_{w2,j}, . . . , I^{s}_{wn,j})is a corresponding standard current dissipation data set of the standard working units.

2. The method of claim 1, wherein the standard current dissipation data (I^{s}_{DC}, I^{s}_{w1,j}, I^{s}_{w2,j}, . . . , I^{s}_{wn,j}) are obtained as follows:
taking a standard IC device, wherein the standard IC device has n standard working units;
operating the standard IC device under the conditions of the m sets of operation parameters (X_{1,j}, X_{2,j}, . . . , X_{n,j}, j=1˜m) to respectively obtain corresponding standard total current dissipations (I^{s}_{t,j}, j=1˜m) of the standard IC device; and
computering the m sets of standard current dissipation data (I^{s}_{w1,j}, I^{s}_{w2,j}, . . . , I^{s}_{wn,j}, j=1˜m) of the standard working units corresponding to the m sets of operation parameters (X_{1,j}, X_{2,j}, . . . , X_{n,j}) and the standard basic current dissipation (I^{s}_{DC}) of the standard IC device by using the standard total current dissipations (I^{s}_{t,j}).

3. The method of claim 1, wherein the IC device is a dynamic random access memory (DRAM) device.

4. The method of claim 1, wherein one of the working units is a core working unit and one of the operation parameters is a row cycle time (tRC) and the current dissipation of the core working unit corresponds to the row cycle time (tRC).

5. The method of claim 1, wherein one of the working units is a peripheral working unit and one of the operation parameters is a clock cycle time (tCK) and the current dissipation of the peripheral working unit corresponds to the clock cycle time (tCK).

6. The method of claim 4, wherein the current dissipation of the core working unit is substantially proportional to the row cycle time (tRC).

7. The method of claim 5, wherein the current dissipation of the peripheral working unit is substantially proportional to the clock cycle time (tCK).

8. A method for analyzing a wafer, wherein the wafer has a plurality of IC devices, said method comprising:
analyzing each of the IC devices by using the method of claim 1 to determine whether each IC device is a defective IC device or a fine IC device; and
calculating the ratio of the number of defective IC devices to that of fine IC devices to determine if the wafer is a defective wafer.
